(19) United States
(12) Patent Application Publication
(10) Pub. No.: US 2026/0367170 A1
(43) Pub. Date: Nov. 19, 2026

(54) SMART LITHIUM CUMULATION DETECTION FOR BATTERIES

(71) Applicant: Lenovo (United States) Inc., Morrisville, NC (US)

(72) Inventors: Bouziane Yebka, Apex, NC (US); Jeremy R. Carlson, Cary, NC (US); Philip J. Jakes, Durham, NC (US)

(21) Appl. No.: 19/209,719

(22) Filed: May 15, 2025

(51) Int. Cl. G01R 31/392; G01R 31/367; G01R 31/3842; G01R 31/389; H01M 4/02; H01M 4/134; H01M 10/0525; H01M 10/44; H02J 7/60

(52) U.S. Cl. CPC G01R 31/392; G01R 31/367; G01R 31/3842; G01R 31/389; H01M 4/134; H01M 10/44; H02J 7/663; H01M 2004/027; H01M 10/0525

(57) ABSTRACT

In one aspect, a device includes a processor system and storage. The storage includes instructions executable by the processor system to monitor one or more metrics related to charge or discharge of a lithium metal battery and, based on the monitoring of the one or more metrics, determine that a trigger associated with excess lithium cumulation has been met. Responsive to determining that the trigger has been met, the instructions are executable to deactivate the lithium metal battery. The metrics may relate to battery temperature, current, impedance, and/or voltage. The trigger may be deviation of the one or more metrics from respective expected levels for at least a threshold period of continuous time. Additionally or alternatively, the trigger may be a threshold number of times being reached, during a predefined time interval, that the one or more metrics deviate from respective expected levels and then return to respective expected levels.

### FIELD

The disclosure below relates to technically inventive, non-routine solutions that are necessarily rooted in computer technology and that produce concrete technical improvements. In particular, the disclosure below relates to techniques for proactive lithium cumulation detection for batteries such as lithium metal batteries.

### BACKGROUND

As recognized herein, manufacturers are starting to produce batteries with excess lithium through a process called pre-lithiation/lithium supplement. The excess lithium can then be absorbed into the cathode after the initial efficiency loss has been undergone by the battery. This allows the battery to still maintain more or less full capacity, notwithstanding the initial-efficiency loss. However, this disclosure recognizes that each battery behaves differently, and if some of the excess lithium is not entirely consumed in the cathode, the excess lithium can significantly impact the battery's state of health quantification and safety over time, as the excess lithium not consumed can still be active. There are currently no adequate solutions to the foregoing technological problems, particularly related to monitoring and remediating battery abnormal behaviors in such circumstances.

### SUMMARY

Accordingly, in one aspect, a device includes a processor system and storage accessible to the processor system. The storage includes instructions executable by the processor system to monitor one or more metrics related to the charge or discharge of a lithium metal battery over a number of charge and discharge cycles for the battery. The instructions are also executable to, based on the monitoring of the one or more metrics over the number of charge and discharge cycles for the battery, determine that a trigger associated with excess lithium cumulation on an anode has been met. The instructions are further executable to, responsive to determining that the trigger has been met, deactivate the lithium metal battery.

In various non-limiting embodiments, the one or more metrics may relate to the temperature of the lithium metal battery during charge and/or to temperature of the lithium metal battery during discharge. Additionally or alternatively, the one or more metrics may relate to discharge current of the lithium metal battery and/or to charge current of the lithium metal battery, such as discharge current of the lithium metal battery under a first expected impedance and/or charge current of the lithium metal battery under a second expected impedance. Also, in some non-limiting examples, the one or more metrics may relate to the discharge current of the lithium metal battery while the lithium metal battery is within a first temperature range and/or to the charge current of the lithium metal battery while the lithium metal battery is within a second temperature range. Still further, the one or more metrics may relate to voltage of the lithium metal battery during charge and/or to voltage of the lithium metal battery during discharge.

What's more, in some example embodiments the trigger may include detection that the one or more metrics have deviated from respective expected levels for at least a threshold period of continuous time. Additionally or alternatively, the trigger may include detection that a threshold number of times have been reached, during a predefined time interval, where the one or more metrics deviated from respective expected levels and then returned to respective expected levels. To eliminate false positives but still help ensure safety, the threshold number of times may be more than two times (e.g., three or more times).

Still further, in some implementations, the determination that the trigger has been met may be made using an output from one or more trained artificial neural networks (ANNs) configured for pattern recognition. In certain instances, the one or more trained ANNs may be executed to determine that the trigger has been met by analyzing the one or more metrics in relation to an expected trend determined from historical data for one or more previous charge or discharge cycles of the lithium metal battery.

Also, in example embodiments, the lithium metal battery may be a lithium-silicon battery. Thus, the anode of the lithium metal battery may include silicon. And if desired, the device may include the lithium metal battery itself.

In another aspect, a method includes analyzing one or more metrics related to the charge or discharge of a lithium metal battery over a number of charge and discharge cycles for the battery. The method also includes, based on the analyzing of the one or more metrics over the number of charge and discharge cycles for the battery, determining that a trigger associated with excess lithium cumulation has been met. The method further includes, responsive to determining that the trigger has been met, deactivating the lithium metal battery.

In some non-limiting examples, deactivating the lithium metal battery may include controlling circuitry to disconnect the battery from a device being powered by the battery.

Also, in non-limiting examples, the one or more metrics may relate to temperature, current, impedance, and/or voltage.

What's more, if desired the trigger may include detection that the one or more metrics have deviated from an expected level for at least a threshold period of continuous time. Additionally or alternatively, the trigger may include detection that a threshold number of times have been reached, during a predefined time interval, that the one or more metrics deviated from respective expected levels and then returned to respective expected levels.

In still another aspect, a battery management system (BMS) includes a processor system configured to analyze one or more metrics related to the charge or discharge of a battery over a number of charge and discharge cycles for the battery. Based on the analysis of the one or more metrics over the number of charge and discharge cycles for the battery, the instructions are executable to determine that a trigger associated with excess battery material cumulation has been met. The processor system is also configured to deactivate the battery responsive to determining that the trigger has been met.

In some example embodiments, the battery may be a lithium-metal battery and the one or more metrics may relate to temperature, current, impedance, and/or voltage. Also, in certain example embodiments, the trigger may include detection that the one or more metrics have deviated from an expected level for at least a threshold period of continuous time. Additionally or alternatively, the trigger may include detection that a threshold number of times have been reached, during a predefined time interval, where the one or more metrics deviated from respective expected levels and then returned to respective expected levels.

### BRIEF DESCRIPTION OF THE DRAWINGS

The details of present principles, both as to their structure and operation, can best be understood in reference to the accompanying drawings, in which like reference numerals refer to like parts, and in which:

FIG. 1 is a block diagram of an example system consistent with present principles;

FIG. 2 shows a chart and schematic diagram related to the first efficiency loss and pre-lithiation of a lithium metal battery consistent with present principles;

FIG. 3 shows various charts that illustrate historical battery data for different metrics as may be collected and stored over time for use by a processor system consistent with present principles;

FIG. 4 shows both historical voltage trends and an expected future voltage trend for a future charge cycle of a lithium metal battery consistent with present principles;

FIGS. 5-22 show various charts illustrating certain considerations and expected charge/discharge trends of lithium metal batteries and complementary charts showing abnormalities that deviate from expected trends consistent with present principles;

FIG. 23 illustrates example logic in flow chart format that may be executed by a processor system consistent with present principles; and

FIG. 24 shows an example of an artificial intelligence (AI) model architecture that is consistent with present principles.

### DETAILED DESCRIPTION

It is to be generally understood consistent with present principles that lithium cumulation may occur when lithium atoms build up on the anode surface of a battery, forming a metallic phase (e.g., film/plating).

But also, generally speaking, lithium cumulation is not an issue for batteries without a supplement (e.g., excess lithium) if the charging procedure is stopped and the cell/battery can rest. This is because the accumulated lithium ions can slowly intercalate into the anode electrode during this rest period. Thus, the process is still reversible given enough relaxation time or a small discharge current (e.g., lithium-stripping) so that the reduced lithium ions can intercalate or be stripped from the anode.

However, irreversible lithium loss is caused by surface growth, parasitic reactions, anode defects, etc., which in turn reduces battery capacity. This is particularly true for lithium-ion batteries with silicon based anode technology. To address this, excess lithium can be intentionally added near the cathode material for high-energy-density silicon-based anodes, creating an accessible Li-reserve that is absorbable into the cathode to compensate for lithium depletion during initial cycling (sometimes referred to as “initial efficiency loss”). But if the excess lithium (supplement) is not entirely consumed, it can significantly impact battery safety over time due to uncontrollable lithium cumulation exaggerated by the excess lithium. For instance, if too much lithium builds up external to the battery cell(s), it can create a safety hazard. The excess lithium can also cause a short in the battery and even a fire.

The present disclosure, therefore, recognizes that monitoring the excess lithium effect is important for optimizing battery performance, accurately gauging available capacity, and ensuring safety. However, prior algebraic equations for calculating capacity do not work and are not reliable for pre-lithiated batteries because the excess lithium does not change the capacity of the materials themselves, so the system still might not know how much excess lithium exists in the battery. The present disclosure also recognizes that visibly inspecting the battery for lithium cumulation is not practical as it involves deconstructing and effectively destroying the battery.

Given the foregoing, the present disclosure recognizes that certain artificial intelligence-based techniques may be used instead. To wit, lithium cumulation can be monitored by measuring the real-time change of successive charge/discharge curves under different conditions and then comparing those curves to detect deviations from what is expected as normal using AI. This technique can help avoid battery failure through a smart-charging protocol that helps monitor the abnormal capacity behavior during charge and discharge while providing an active safety control via battery deactivation (permanent, intentional failure) based on a threshold being met. This allows for a state of health quantification (e.g., gauging), supplementing lithium benefits over time.

Expectations for “normal” can include a consecutive discharge curve under the same current being similar to or lower than the immediately previous one. It might also include a consecutive charge curve under the same current being similar to or lower than the immediately previous one. Another expectation is that the higher the discharge current, the lower the capacity of the battery. Other expectations include discharge at lower temperatures delivering lower voltage and lower capacity, and conversely, discharge at higher temperatures delivering higher volume and higher capacity.

Present principles may apply to various types of lithium batteries, including those with the following cathodes: lithium cobalt oxide (LCO), lithium manganese oxide (LMO), lithium nickel manganese cobalt oxide (NMC), lithium iron phosphate (LFP), and lithium nickel cobalt aluminum oxide (NCA); and including those with the following anodes: graphite, graphite-silicon composite, silicon lithium metal-based anodes and lithium alloy-based anodes. Anode-less batteries are also encompassed by present principles.

Prior to delving further into the details of the instant techniques, note with respect to any computer systems discussed herein that a system may include server and client components, connected over a network such that data may be exchanged between the client and server components. The client components may include one or more computing devices including televisions (e.g., smart TVs, Internet-enabled TVs), computers such as desktops, laptops and tablet computers, so-called convertible devices (e.g., having a tablet configuration and laptop configuration), and other mobile devices including smart phones. These client devices may employ, as non-limiting examples, operating systems from Apple Inc. of Cupertino CA, Google Inc. of Mountain View, CA, or Microsoft Corp. of Redmond, WA. A Unix® or similar such as Linux® operating system may be used, as may a Chrome or Android or Windows or macOS or iOS operating system. These operating systems can execute one or more browsers such as a browser made by Microsoft or Google or Mozilla or another browser program that can access web pages and applications hosted by Internet servers over a network such as the Internet, a local intranet, or a virtual private network.

As used herein, instructions refer to computer-implemented steps for processing information in the system. Instructions can be implemented in software, firmware or hardware, or combinations thereof and include any type of programmed step undertaken by components of the system; hence, illustrative components, blocks, modules, circuits, and steps are sometimes set forth in terms of their functionality.

A processor may be any single-or multi-chip processor that can execute logic by means of various lines such as address lines, data lines, and control lines and registers and shift registers. Moreover, any logical blocks, modules, and circuits described herein can be implemented or performed with a system processor such as a central processing unit (CPU), a graphics processing unit (GPU), a neural processing unit (NPU), a digital signal processor (DSP), a field programmable gate array (FPGA) or other programmable logic device such as an application specific integrated circuit (ASIC), discrete gate or transistor logic, discrete hardware components, or any combination thereof designed to perform the functions described herein. A processor can also be implemented by a controller or state machine or a combination of computing devices. Thus, the methods herein may be implemented as software instructions executed by a processor, suitably configured application specific integrated circuits (ASIC) or field programmable gate array (FPGA) modules, or any other convenient manner as would be appreciated by those skilled in the art. Where employed, the software instructions may also be embodied in a non-transitory device that is being vended and/or provided, and that is not a transitory, propagating signal and/or a signal per se. For instance, the non-transitory device may be or include a hard disk drive, solid state drive, or CD ROM. Flash drives may also be used for storing the instructions. Additionally, the software code instructions may also be downloaded over the Internet (e.g., as part of an application (“app”) or software file). Accordingly, it is to be understood that although a software application for undertaking present principles may be vended with a device such as the system 100 described below, such an application may also be downloaded from a server to a device over a network such as the Internet. An application can also run on a server and associated presentations may be displayed through a browser (and/or through a dedicated companion app) on a client device in communication with the server.

Software modules and/or applications described by way of flow charts and/or user interfaces herein can include various sub-routines, procedures, etc. Without limiting the disclosure, logic stated to be executed by a particular module can be redistributed to other software modules and/or combined together in a single module and/ or made available in a shareable library. Also, the user interfaces (UI)/graphical UIs described herein may be consolidated and/or expanded, and UI elements may be mixed and matched between UIs.

Logic when implemented in software, can be written in an appropriate language such as but not limited to hypertext markup language (HTML)-5, Java®/JavaScript, C #or C++, and can be stored on or transmitted from a computer-readable storage medium such as a hard disk drive (HDD) or solid state drive (SSD), a random access memory (RAM), read-only memory (ROM), electrically erasable programmable read-only memory (EEPROM), a hard disk drive or solid state drive, compact disk read-only memory (CD-ROM) or other optical disk storage such as digital versatile disc (DVD), magnetic disk storage or other magnetic storage devices including removable thumb drives, etc.

In an example, a processor can access information over its input lines from data storage, such as the computer readable storage medium, and/or the processor can access information wirelessly from an Internet server by activating a wireless transceiver to send and receive data. Data typically is converted from analog signals to digital by circuitry between the antenna and the registers of the processor when being received and from digital to analog when being transmitted. The processor then processes the data through its shift registers to output calculated data on output lines, for presentation of the calculated data on the device.

Components included in one embodiment can be used in other embodiments in any appropriate combination. For example, any of the various components described herein and/or depicted in the Figures may be combined, interchanged or excluded from other embodiments.

The term “a” or “an” in reference to an entity refers to one or more of that entity. As such, the terms “a” or “an”, “one or more”, and “at least one” can be used interchangeably herein. “A system having at least one of A, B, and C” (likewise “a system having at least one of A, B, or C” and “a system having at least one of A, B, C”) includes systems that have A alone, B alone, C alone, A and B together, A and C together, B and C together, and/or A, B, and C together, etc.

The term “circuit” or “circuitry” may be used in the summary, description, and/or claims. The term “circuitry” includes all levels of available integration, e.g., from discrete logic circuits to the highest level of circuit integration such as VLSI, and includes programmable logic components programmed to perform the functions of an embodiment as well as processors (e.g., special-purpose processors) programmed with instructions to perform those functions.

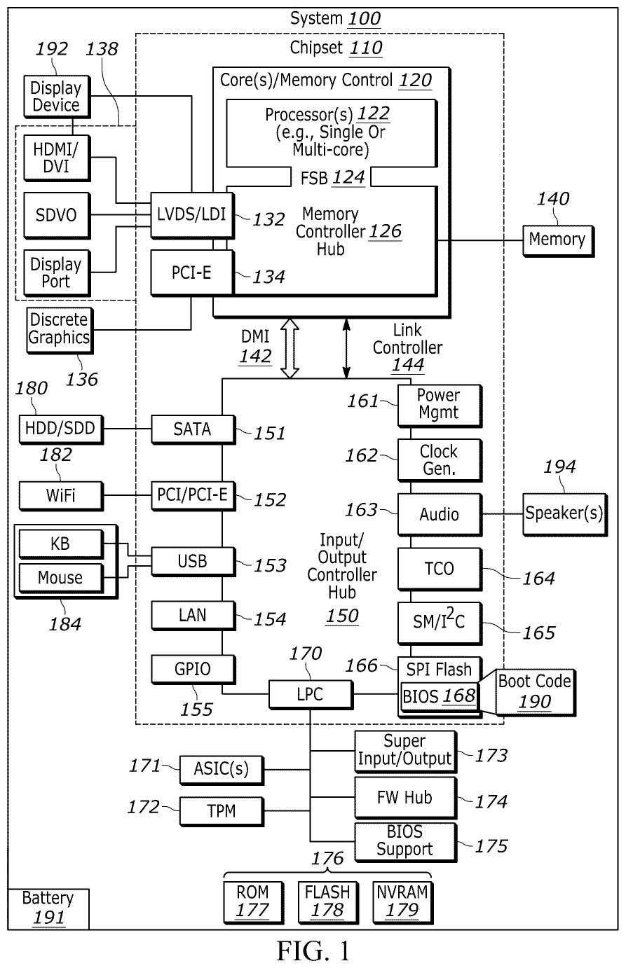

Now specifically in reference to FIG. 1, an example block diagram of an information handling system and/or computer system 100 is shown that is understood to have a housing for the components described below. Note that in some embodiments the system 100 may be a desktop computer system, such as one of the ThinkCentre®, or notebook computer system, such as ThinkPad® series of personal computers sold by Lenovo (US) Inc. of Morrisville, NC, or a workstation computer, such as the ThinkStation®, which are sold by Lenovo (US) Inc. of Morrisville, NC; however, as apparent from the description herein, a client device, a server or other machine in accordance with present principles may include other features or only some of the features of the system 100. Also, the system 100 may be, e.g., a game console such as XBOX®, and/or the system 100 may include a mobile communication device such as a mobile telephone, notebook computer, and/or other portable computerized device.

As shown in FIG. 1, the system 100 may include a so-called chipset 110. A chipset refers to a group of integrated circuits, or chips, that are designed to work together. Chipsets are usually marketed as a single product (e.g., consider chipsets marketed under the brands INTEL®, AMD®, etc.).

In the example of FIG. 1, the chipset 110 has a particular architecture, which may vary to some extent depending on brand or manufacturer. The architecture of the chipset 110 includes a core and memory control group 120 and an I/O controller hub 150 that exchange information (e.g., data, signals, commands, etc.) via, for example, a direct management interface or direct media interface (DMI) 142 or a link controller 144. In the example of FIG. 1, the DMI 142 is a chip-to-chip interface (sometimes referred to as being a link between a “northbridge” and a “southbridge”).

The core and memory control group 120 includes a processor system 122 (e.g., one or more single core or multi-core processors, etc.) and a memory controller hub 126 that exchange information via a front side bus (FSB) 124. A processor system such as the system 122 may therefore include one or more processors acting independently or in concert with each other to execute an algorithm, whether those processors are in one device or more than one device. Additionally, as described herein, various components of the core and memory control group 120 may be integrated onto a single processor die, for example, to make a chip that supplants the “northbridge” style architecture.

The memory controller hub 126 interfaces with memory 140. For example, the memory controller hub 126 may provide support for DDR SDRAM memory (e.g., DDR, DDR2, DDR3, etc.). In general, the memory 140 is a type of random-access memory (RAM). It is often referred to as “system memory.”

The memory controller hub 126 can further include a low-voltage differential signaling interface (LVDS) 132. The LVDS 132 may be a so-called LVDS Display Interface (LDI) for support of a display device 192 (e.g., a CRT, a flat panel, a projector, a touch-enabled light emitting diode (LED) display or other video display, etc.). A block 138 includes some examples of technologies that may be supported via the LVDS interface 132 (e.g., serial digital video, HDMI/DVI, display port). The memory controller hub 126 also includes one or more PCI-express interfaces (PCI-E) 134, for example, for support of discrete graphics 136. For example, the memory controller hub 126 may include a 16-lane (x16) PCI-E port for an external PCI-E-based graphics card (including, e.g., one or more GPUs). An example system may thus include PCI-E for support of graphics.

In examples in which it is used, the I/O hub controller 150 can include a variety of interfaces. The example of FIG. 1 includes a SATA interface 151, one or more PCI-E interfaces 152 (optionally one or more legacy PCI interfaces), one or more universal serial bus (USB) interfaces 153, a local area network (LAN) interface 154 (more generally a network interface for communication over at least one network such as the Internet, a WAN, a LAN, a Bluetooth network using Bluetooth 5.0 communication, etc. under direction of the processor(s) 122), a general purpose I/O interface (GPIO) 155, a low-pin count (LPC) interface 170, a power management interface 161, a clock generator interface 162, an audio interface 163 (e.g., for speakers 194 to output audio), a total cost of operation (TCO) interface 164, a system management bus interface (e.g., a multi-master serial computer bus interface) 165, and a serial peripheral flash memory/controller interface (SPI Flash) 166, which, in the example of FIG. 1, includes basic input/output system (BIOS) 168 and boot code 190. With respect to network connections, the I/O hub controller 150 may include integrated gigabit Ethernet controller lines multiplexed with a PCI-E interface port. Other network features may operate independent of a PCI-E interface. Example network connections include Wi-Fi as well as wide-area networks (WANs) such as 4G and 5G cellular networks.

The interfaces of the I/O hub controller 150 may provide for communication with various devices, networks, etc. For example, where used, the SATA interface 151 and/or PCI-E interface 152 provide for reading, writing or reading and writing information on one or more drives 180 such as HDDs, SSDs or a combination thereof, but in any case the drives 180 are understood to be, e.g., tangible computer readable storage mediums that are not transitory, propagating signals. The I/O hub controller 150 may also include an advanced host controller interface (AHCI) to support one or more drives 180. The PCI-E interface 152 allows for wireless connections 182 to devices, networks, etc. The USB interface 153 provides for input devices 184 such as keyboards (KB), mice and various other devices (e.g., cameras, phones, storage, media players, etc.).

In the example of FIG. 1, the LPC interface 170 provides for use of one or more ASICs 171, a trusted platform module (TPM) 172, a super I/O 173, a firmware hub 174, BIOS support 175 as well as various types of memory 176 such as ROM 177, Flash 178, and non-volatile RAM (NVRAM) 179. With respect to the TPM 172, this module may be in the form of a chip that can be used to authenticate software and hardware devices. For example, a TPM may be capable of performing platform authentication and may be used to verify that a system seeking access is the expected system.

The system 100, upon power on, may be configured to execute boot code 190 for the BIOS 168, as stored within the SPI Flash 166, and thereafter processes data under the control of one or more operating systems and application software (e.g., stored in system memory 140). An operating system may be stored in any of a variety of locations and accessed, for example, according to instructions of the BIOS 168.

As also shown in FIG. 1, the system 100 may include a battery 191, such as a single-cell battery or battery pack with multiple cells. In addition to containing one or more battery cells, the battery 191 may include its own one or more processors, such as a microprocessor or any other type of processor that might be provided as part of a gas gauge or battery management system (BMS) for the battery 191. Non-transitory storage may also be included in the battery 191, with the storage storing firmware used to monitor the battery 191 and perform other functions described below. Random access memory (RAM) and other components may also be included in the battery 191, such as one or more sensors for sensing/measuring real-time metrics related to the battery 191 and/or battery cells within, such as temperature, voltage, current, impedance, state of charge (SOC), etc. Thus, these sensors may provide input/measurements to the processor(s) within the battery 191 and/or the processor(s) 122 consistent with present principles.

Additionally, note that the one or more battery cells within the battery 191 may be configured in jellyroll format. The cells may also be configured in pouch cell format in which the strip(s) of active material are folded, or in a stacked format if desired. Regardless, the battery cells may be Lithium metal battery cells and/or other types of battery cells consistent with present principles.

It is to be further understood consistent with present principles that the battery 191 may be electrically coupled to and power the system 100, and/or individual components thereof, using battery power discharged from the battery 191. The system 100 and/or battery 191 in particular may also be electrically coupled to at least one charge receiver on the system 100 for receiving a charge via an AC/DC power supply connected to an AC power source (e.g., a wall outlet providing AC power) to charge the one or more battery cells in the battery 191. Thus, the charge receiver may include at least one circuit configured for receiving power from a wall outlet (or other AC power source) via the power supply and then providing power to the system 100 to power it and also providing power to the battery 191 to charge the cells within the battery 191. In some examples, wireless charging using a wireless charge receiver and wireless charge transmitting pad may be used.

Notwithstanding the foregoing, it is to be understood that a battery consistent with present principles need not necessarily be a smart battery as set forth above and may instead be established by one or more battery cells while not including a processor, storage, etc. as mentioned above. Here, the CPU of the system or another processor like a DPS might undertake functions set forth further below.

Additionally, though not shown for simplicity, in some embodiments the system 100 may include a gyroscope that senses and/or measures the orientation of the system 100 and provides related input to the processor system 122, an accelerometer that senses acceleration and/or movement of the system 100 and provides related input to the processor system 122, and/or a magnetometer that senses and/or measures directional movement of the system 100 and provides related input to the processor system 122.

Still further, the system 100 may include an audio receiver/microphone that provides input from the microphone to the processor system 122 based on audio that is detected, such as via a user providing audible input to the microphone. The system 100 may also include a camera that gathers one or more images and provides the images and related input (e.g., metadata like an image timestamp) to the processor system 122. The camera may be a thermal imaging camera, an infrared (IR) camera, a digital camera such as a webcam, a three-dimensional (3D) camera, and/or a camera otherwise integrated into the system 100 and controllable by the processor system 122 to gather still images and/or video.

Also, the system 100 may include a global positioning system (GPS) transceiver that is configured to communicate with satellites to receive/identify geographic position information and provide the geographic position information to the processor system 122. However, it is to be understood that another suitable position receiver other than a GPS receiver may be used in accordance with present principles to determine the location of the system 100.

It is to be understood that an example client device or other machine/computer may include fewer or more features than shown on the system 100 of FIG. 1. In any case, it is to be understood at least based on the foregoing that the system 100 is configured to undertake present principles.

Present principles may employ various machine learning models, including deep learning models. Machine learning models consistent with present principles may use various algorithms trained in ways that include supervised learning, unsupervised learning, semi-supervised learning, reinforcement learning, feature learning, self-learning, and other forms of learning. Examples of such algorithms, which can be implemented by computer circuitry, include one or more neural networks, such as a convolutional neural network (CNN), a recurrent neural network (RNN), and a type of RNN known as a long short-term memory (LSTM) network. Attention-based architectures or transformer-based architectures may be used. Generative pre-trained transformers (GPT) also may be used. Support vector machines (SVM) and Bayesian networks also may be considered to be examples of machine learning models. In addition to the types of networks set forth above, models herein may be implemented by classifiers.

As understood herein, performing machine learning may therefore involve accessing and then training a model on training data to enable the model to process further data to make inferences. An artificial neural network trained through machine learning may thus include an input layer, an output layer, and multiple hidden layers in between that are configured and weighted to make inferences about an appropriate output.

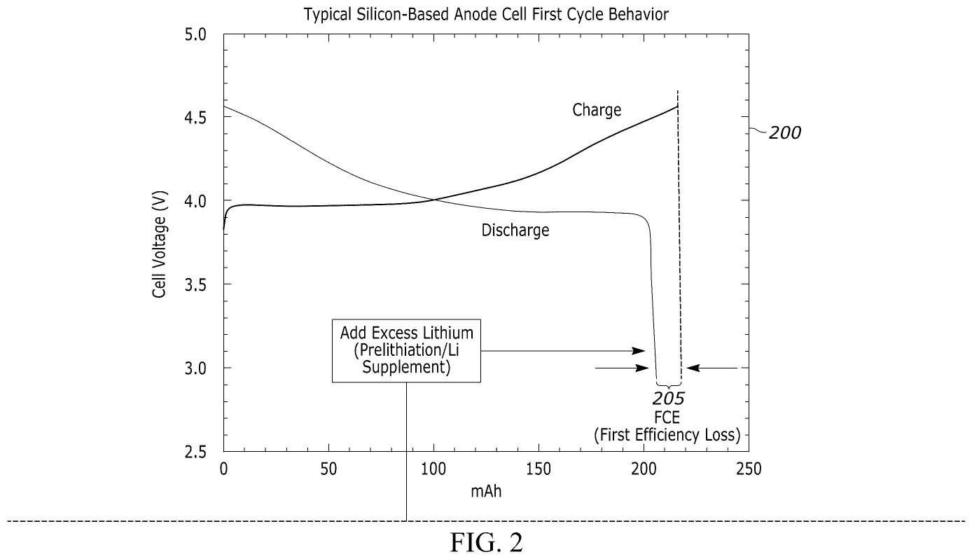

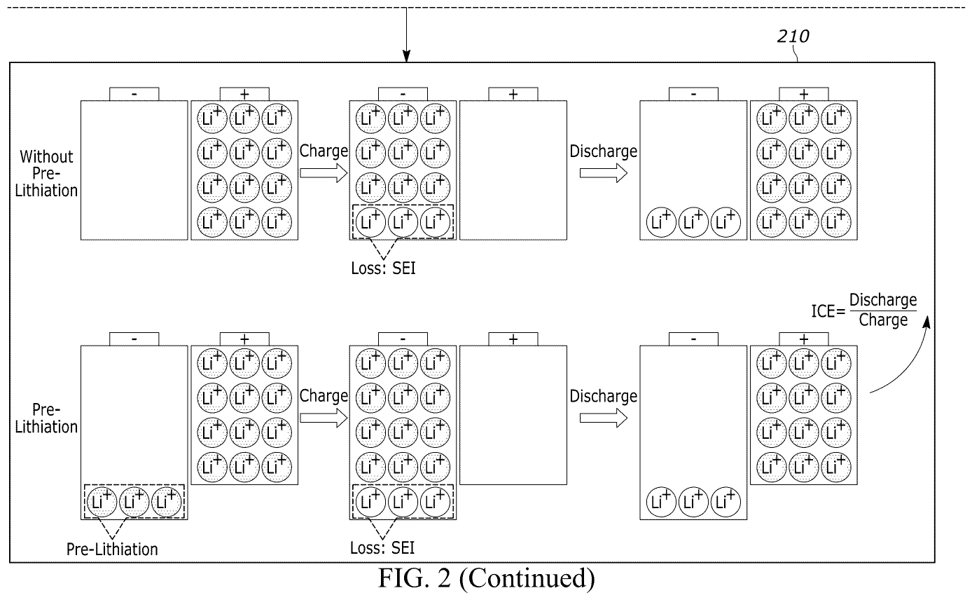

Refer now to FIG. 2. This figure shows a chart 200 and schematic diagram 210. The chart 200 demonstrates first efficiency loss of a lithium metal battery, and the schematic 210 demonstrates pre-lithiation of the lithium metal battery (with silicon anode, e.g., no graphite or negligible graphite) to remediate first efficiency loss. As shown in the chart 200, as voltage drops during a first discharge of the battery post-manufacturing, some lithium from inside the battery is permanently lost and cannot be used for ensuing charge and discharge cycles, as demonstrated by the gap 205.

As discussed above, the manufacturer may therefore add excess lithium at manufacture that is beyond the amount absorbable into the cathode and/or anode of the battery, but may be absorbed into the anode and/or cathode during ensuing charge or discharge cycles (after first-efficiency loss) using the capacity created by the first efficiency loss. The schematic 210 thus demonstrates on the top line that without pre-lithiation, there can be a loss of lithium cations during a first charge of the battery post-manufacturing, resulting in overall loss of total potential capacity of the battery on subsequent charges and discharges, due to solid electrolyte interphase (e.g., forming a passivation layer on the battery's electrode surface during the first charge/discharge cycle(s)). But the bottom line of the schematic 210 illustrates that with pre-lithiation, once first efficiency loss occurs at the anode during the first charge cycle, otherwise excess lithium from pre-lithiation may be absorbed into the cathode during discharge for the battery to regain some or all of its lost capacity.

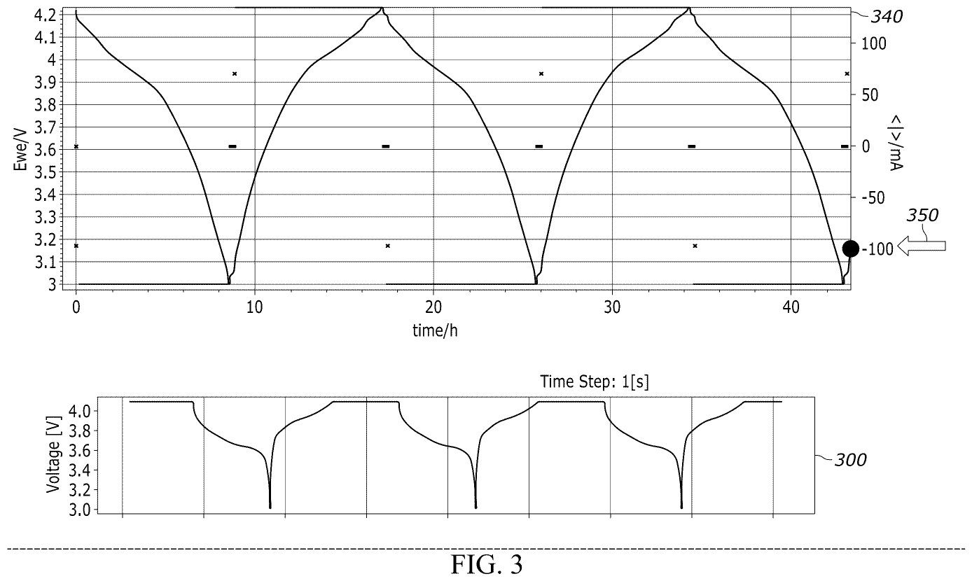

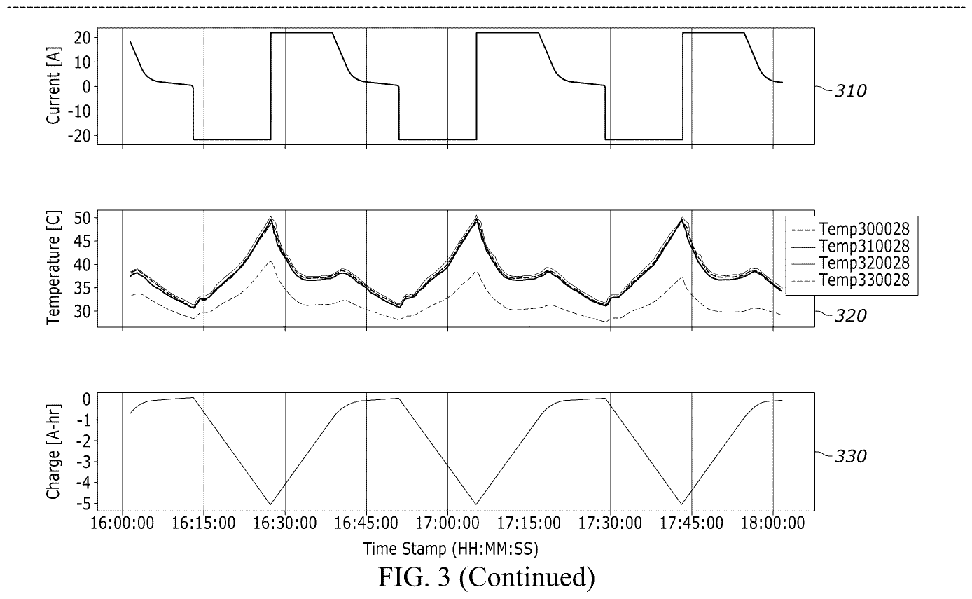

Moving on to FIG. 3, four charts are shown that illustrate historical battery data for different battery metrics that may be collected and stored over time during post-first efficiency loss charge and discharge cycles of a lithium metal battery. Chart 300 illustrates an example voltage history over time, chart 310 illustrates an example current history over time, chart 320 illustrates an example temperature history over time, and chart 330 illustrates an example charge over time in amps/hour. The battery's BMS or another portion of the device in which the battery is housed may use its circuitry to collect this data over time and save it to persistent storage internal or external to the battery itself. Chart 340 illustrates historical voltage trends 400 up to a current charge point 350.

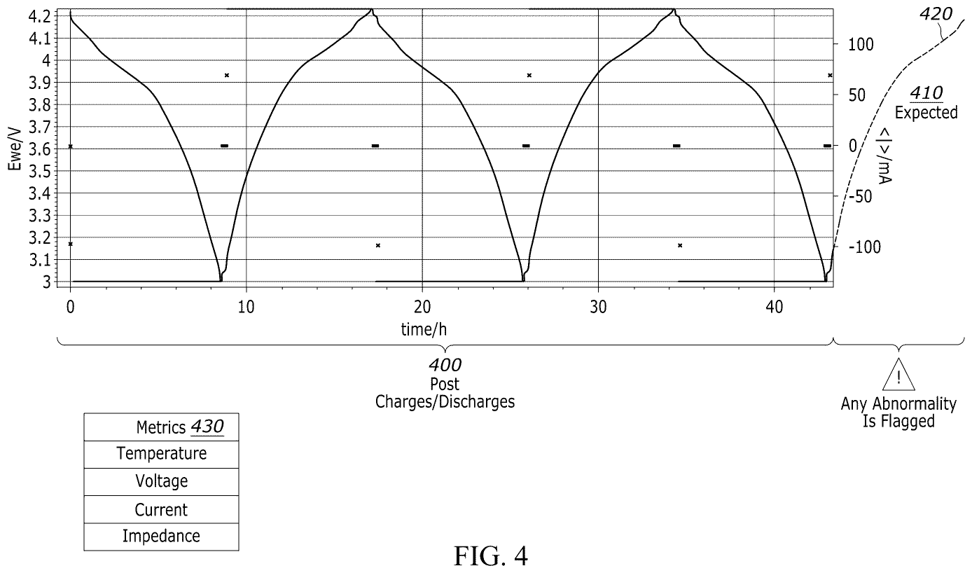

Turning to FIG. 4, this figure shows both the historical voltage trends 400 of past charge/discharge cycles and an expected future voltage trend 410 of a future charge cycle (next immediate) for a lithium metal battery. This figure therefore illustrates expected battery behavior during full or partial charges, and during full or partial discharges. Note that trend 420 indicates an expected voltage trend over time during a next charge cycle, resulting in expected voltage levels at various future times. Should the actual voltage level during the actual next immediate charge cycle then deviate from what is expected, this abnormality may be flagged by the system.

Flagging itself may include noting the abnormality in a log and/or deactivating the battery itself. In some examples, a single abnormality being recognized may trigger battery deactivation. However, in other examples to reduce false positives while still helping with battery safety, triggers for battery deactivation may also be more than a single instance of abnormality, as set forth in greater detail below.

But still in reference to FIG. 4, note that this figure also illustrates various example metrics 430 that may be monitored in real time for determining whether an abnormality exists in lithium metal battery charging or discharging. Specifically, as non-limiting examples, the metrics 430 may include battery temperature, voltage, current, and/or impedance as sensed during battery charge and battery discharge.

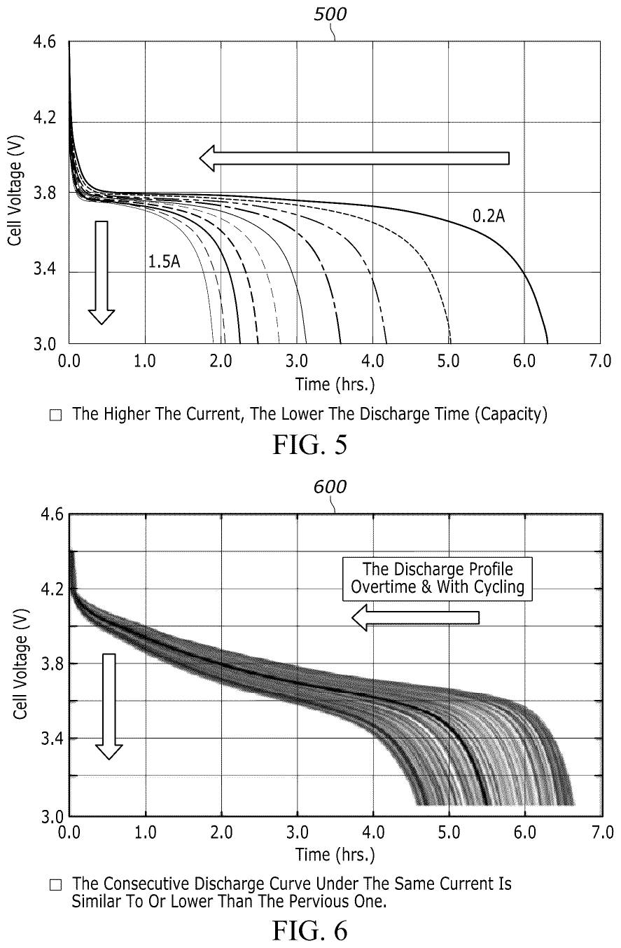

Now in reference to FIG. 5, current considerations consistent with present principles are illustrated through the consecutive discharge curves shown in the chart 500. The chart 500 demonstrates that the higher the current during discharge, the lower the discharge time (and thus capacity).

The chart 600 of FIG. 6 then illustrates battery cycling considerations consistent with present principles. FIG. 6 shows showing a discharge profile (curves) over time and with cycling. The chart 600 thus demonstrates that consecutive discharge curves for consecutive (successive) battery discharges under the same current (load) are expected to be similar to or lower than the immediately previous battery discharge curve.

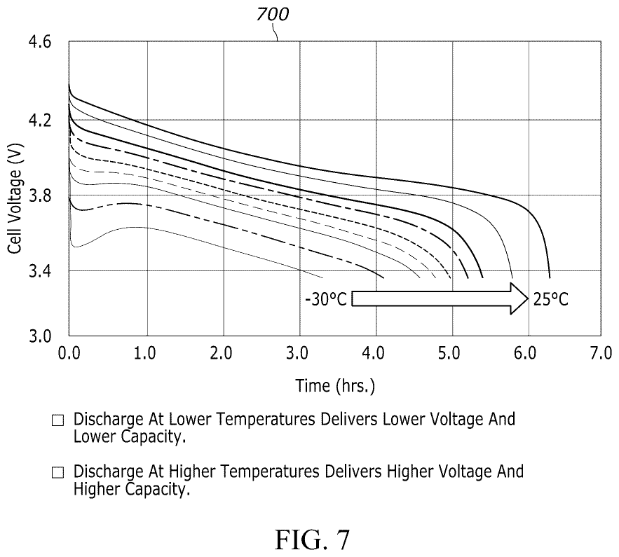

FIG. 7 shows a chart 700 illustrating temperature considerations through discharge curves consistent with present principles. As illustrated by the chart 700, discharging the lithium metal battery at progressively lower temperatures results in progressively lower total battery voltage and progressively lower total battery capacity. Conversely, discharging the battery at progressively higher temperatures results in progressively higher total battery voltage and progressively higher total battery capacity.

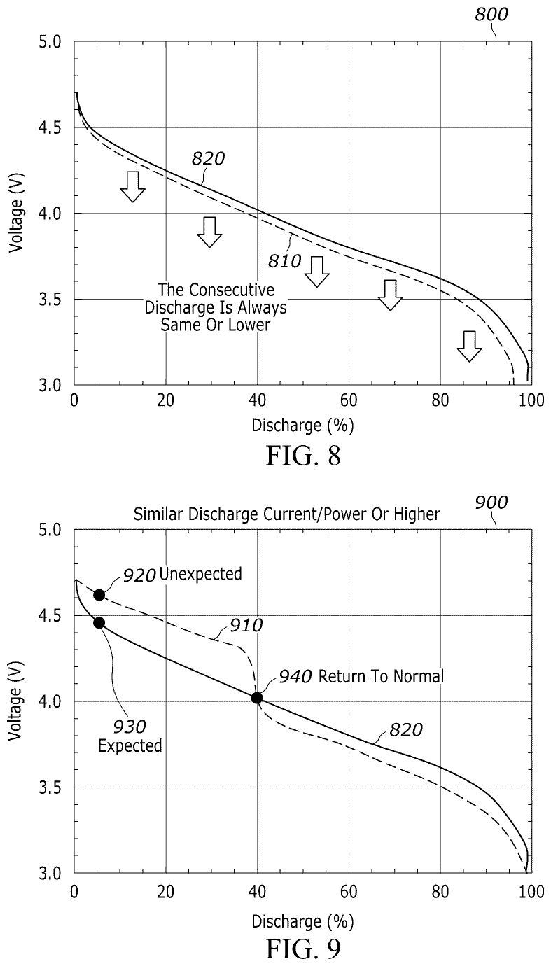

Now in reference to FIG. 8, this figure shows a chart 800 illustrating a cycling consideration in that a future successive discharge voltage 810 is expected to be the same as or lower than the immediately prior discharge voltage 820 (e.g., under similar conditions such as load and operating temperature). However, FIG. 9 illustrates an unexpected abnormality may be identified to then determine whether to deactivate the battery over a potential safety hazard consistent with present principles (due to potential excessive lithium cumulation). The chart 900 therefore shows the immediately prior discharge 820 again, but also shows that a subsequent (current/real-time) consecutive discharge under similar conditions results in a trend 910 with an unexpectedly high voltage for battery discharge between one hundred percent state of charge (SOC) and sixty percent SOC (the first forty percent SOC from fully charged). It may thus be appreciated that while actual voltage at a certain point 920 is above 4.5V, expected voltage at that point 930 was expected to be below 4.5V. This abnormality may be noted and stored by the system in a log, even if voltage returns to normal at a later point 940 in time in the discharge cycle and then subsequently goes below the previous voltage as expected at various latter stages of discharge.

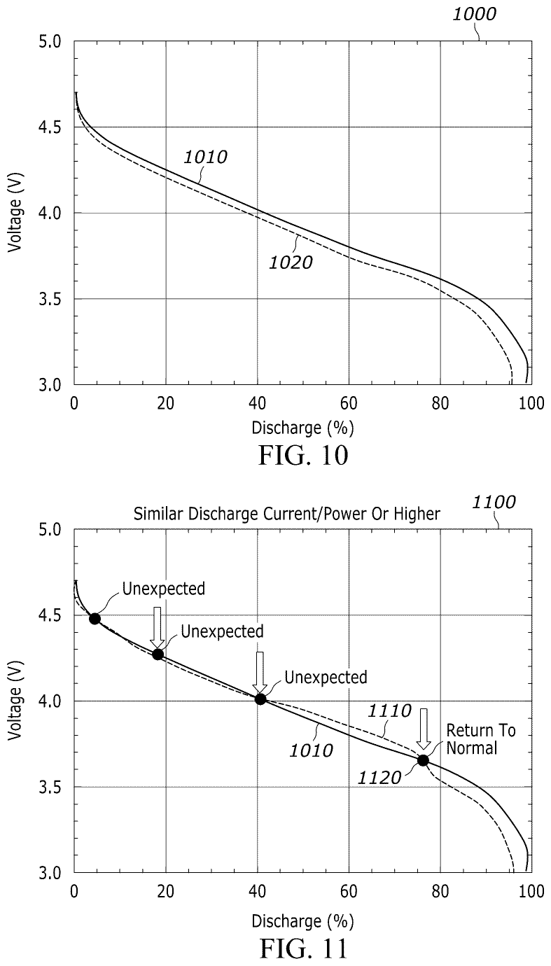

FIGS. 10 and 11 show another example in terms of cycling considerations. The chart 1000 of FIG. 10 shows an immediately previous discharge voltage trend 1010 and an expected immediately next discharge voltage trend 1020 under similar discharge current/power or higher. The chart 1000 therefore demonstrate what is expected-voltage will be slightly lower than the previous discharge cycle during the next discharge cycle.

However, the chart 1100 of FIG. 11 demonstrates that due to potential excessive lithium cumulation, the actual voltage trend 1110 of the immediately next discharge cycle (a current discharge cycle) under a similar discharge current actually results in unexpected voltage fluctuations. Specifically, per this example voltage for the current trend 1110 fluctuates up and down repeatedly above and below the line 1010 for the prior voltage trend before returning to “normal” (expected) behavior beyond point 1120. These instances of unexpectedly high and low voltage deviating from what is expected may be flagged for potentially deactivating the battery at a later time consistent with present principles.

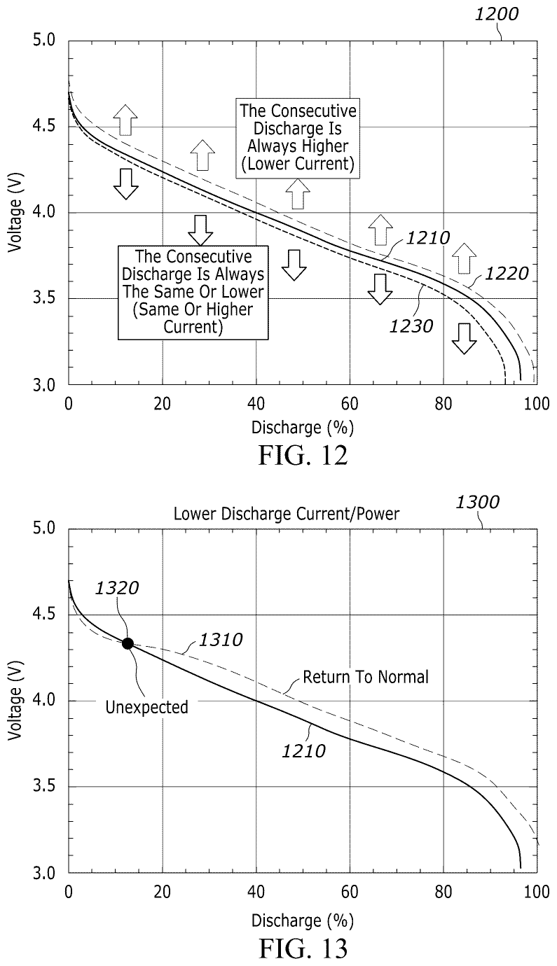

Turning to FIGS. 12 and 13, these figures illustrate discharge rate considerations in relation to battery voltage and potential excessive lithium cumulation. As shown in the chart 1200 of FIG. 12, the middle line 1210 indicates a baseline immediately prior discharge. The lower line 1230 illustrates an expected (and acceptable) discharge for a next discharge cycle when high energy-consuming applications (“apps”) are being used (e.g., video streaming apps) and therefore the load on the battery is higher than for the line 1210, while the upper line 1220 illustrates expected (and acceptable) discharge when relatively less energy-consuming apps are being used (e.g., email and word processing) and therefore the load on the battery is lower than for the line 1210.

FIG. 12 therefore demonstrates that expected discharge may vary depending on the types and amounts of individual software apps being executed by the device's operating system and the corresponding load on the battery. Thus, for the line 1220, a successive discharge voltage is expected to be higher over time (lower current) than the prior discharge 1210 for lower energy-consuming apps. For the line 1230, a successive discharge voltage is expected to be the same or lower over time (same or higher current) than the prior discharge 1210 for high energy-consuming apps.

Now referring to FIG. 13, this chart 1300 continues with the example of FIG. 12 regarding low energy consuming apps and, therefore, less load on the battery than the immediately prior discharge. As shown, at the beginning of discharge from one hundred percent to just below eighty percent SOC, the line 1310 for actual discharge rate is lower than the baseline 1210 from FIG. 12 (for the prior discharge) before returning to normal at the crossover point 1320. As such, this abnormality (lower voltage despite less load on the battery) may be flagged consistent with present principles.

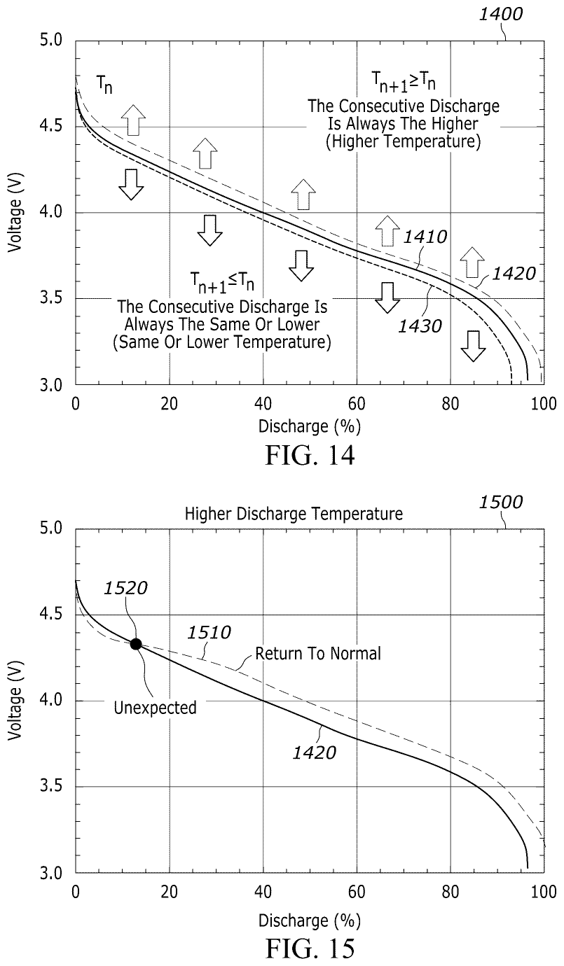

Turning to FIGS. 14 and 15, these figures demonstrate temperature considerations in relation to battery voltage and potential excessive lithium cumulation during discharge. As shown in the chart 1400 of FIG. 14, the middle line 1410 indicates a baseline immediately prior discharge. However, the upper line 1420 illustrates expected (and acceptable) discharge for a next discharge cycle when the battery is operating under a relatively higher temperature than when the baseline 1410 was taken (e.g., due to ambient temperature and/or heat given off by other computing components near the battery making the temperature of the battery higher). The lower line 1430 illustrates expected (and acceptable) discharge for the next discharge cycle when the battery is operating under a relatively lower temperature than when the baseline 1410 was taken.

FIG. 14 therefore demonstrates that expected discharge voltage trends may vary depending on the real-time temperature of the battery for a present discharge cycle being above or below the immediately prior temperature for the immediately prior discharge cycle. Thus, for the line 1420, a successive/consecutive discharge voltage trend is expected to be higher (with higher temperature) than the prior discharge 1410. For line 1430, a successive/consecutive discharge voltage trend is expected to be the same or lower over time (with same or lower temperature) than the prior discharge 1410.

Turning to FIG. 15, this chart 1500 continues with the example of FIG. 14 regarding a relatively higher operating temperature. As shown, even with the battery operating at a relatively higher temperature than the immediately prior discharge, at the beginning of discharge from one hundred percent to just below eighty percent SOC, the line 1510 for actual real-time discharge rate is lower than the baseline curve 1410 (prior discharge curve) from FIG. 14. The line 1510 then returns to normal at the crossover point 1520 and goes back above the line 1410. As such, this abnormality (lower voltage despite higher temperature) may be flagged consistent with present principles.

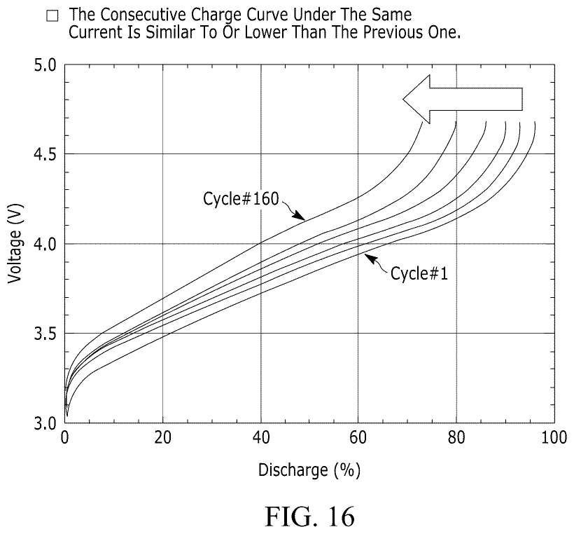

Turning to FIG. 16, this figure demonstrates cycling considerations. It is to be understood that consecutive charge curves under the same current/load (and possibly other similar conditions like similar temperature and corresponding impedance affected by temperature) are expected to be similar to or lower than the immediately previous respective charge curve.

It is to also be understood that cycling degradation in lithium batteries may be based on the progressive deterioration in performance that can occur during repeated charge and discharge cycles over time. Different aging mechanisms (e.g., calendric and cyclic) can occur simultaneously when batteries age. Calendric aging may refer to the gradual degradation of batteries over time, even if the battery is not being used. Cyclic aging may refer to the wear and tear batteries sustain with each charge and discharge cycle. Each aging mechanism may impact the battery's capacity behavior and be considered by an AI model as a metric consistent with present principles.

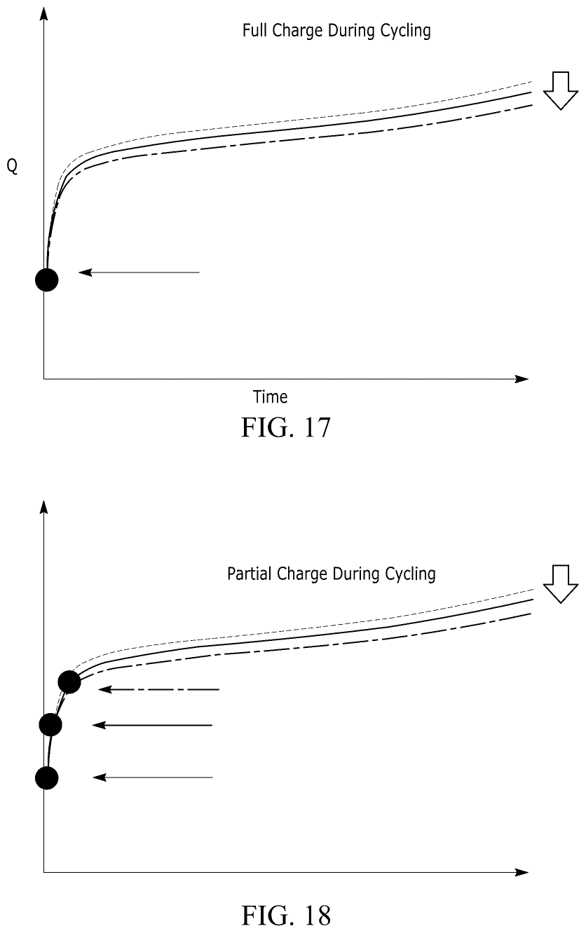

Continuing the detailed description in reference to FIGS. 17 and 18, these figures demonstrate full charge and partial charge, respectively, during cycling. A partial charge on a lithium battery generally may have a positive effect on its cycling life, meaning partial charges that do not reach 100% SOC/full capacity can significantly extend the number of charge-discharge cycles the battery can endure before experiencing significant capacity degradation, as compared to fully charging and discharging the battery frequently. This is often because partial charging puts less stress on the battery's internal chemistry, minimizing the formation of damaging byproducts during the charging process. With this in mind, it may be appreciated from FIGS. 17 and 18 that a consecutive partial charge follows a similar trend and behavior as a full charge but at a lower voltage level.

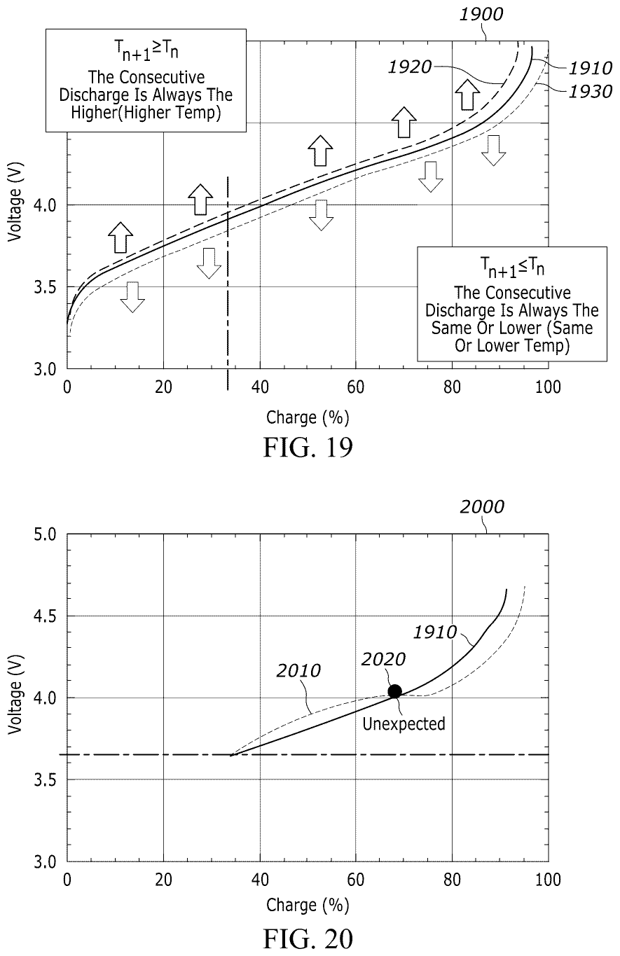

FIGS. 19 and 20 further illustrate present principles. These figures demonstrate temperature considerations in relation to battery voltage and potential excessive lithium cumulation during charging. As shown in the chart 1900 of FIG. 19, the middle line 1910 indicates a baseline immediately prior charge. However, the upper line 1920 illustrates expected (and acceptable) charge when the battery is operating under a relatively higher temperature (and therefore relatively lower impedance) than when the baseline 1910 was taken. The lower line 1930 illustrates expected (and acceptable) charge when relatively the battery is operating under a relatively lower temperature (and therefore relatively higher impedance) than when the baseline 1910 was taken.

FIG. 19 therefore demonstrates that expected charge voltage trends may vary depending on the current operating temperature for a current charge cycle being above or below the prior operating temperature during the prior charge cycle. Thus, for the line 1920, a successive/consecutive charge voltage trend is expected to be higher (due to higher temperature) than the immediately prior discharge 1910. For line 1930, a successive/consecutive charge voltage trend is expected to be the same or lower over time (due to the same or lower temperature) than the prior charge 1910.

Turning to FIG. 20, this chart 2000 continues with the example of FIG. 19 regarding a relatively lower operating temperature than an immediately prior charge cycle. As shown, even with the battery operating at a relatively lower temperature than the immediately prior charge, at the beginning of a partial charge from roughly thirty five percent to above sixty percent SOC, the line 2010 for actual charge rate is higher than the baseline 1910 from FIG. 19, which is inconsistent with what would be expected according to the disclosure above. The line 2010 then returns to normal at the crossover point 2020 and goes below the line 1910. As such, this abnormality (higher voltage over time despite lower temperature) may be flagged consistent with present principles.

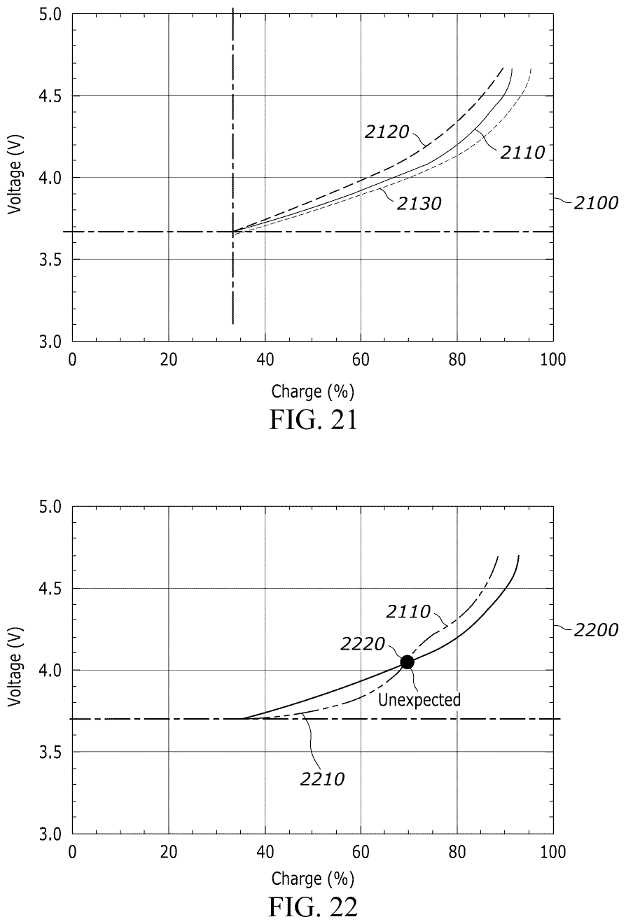

Turning to FIGS. 21 and 22, these figures illustrate charge rate considerations in relation to battery voltage and potential excessive lithium cumulation during high-demand and low-demand times in terms energy/load. As shown in the chart 2100 of FIG. 21, the middle line 2110 indicates a baseline immediately prior partial charge. However, the lower line 2130 illustrates expected (and acceptable) charge that is slower over time when high energy-consuming apps (and more load) are being used, while the upper line 2120 illustrates expected (and acceptable) charge that is faster when relatively less energy-consuming apps (and less load) are being used.

FIG. 21 therefore demonstrates that expected charge may vary depending on the types and amounts of individual software apps being executed by the device's operating system (and therefore the corresponding higher or lower load being drawn from the battery compared to the immediately prior charge cycle). Thus, for the line 2120, a successive charge voltage is expected to be higher over time than the prior discharge 2110 for lower energy-consuming apps and less load being applied compared to the prior cycle. For line 2130, a successive charge voltage is expected to be the same or lower over time (same or higher current) than the prior charge 2110 for high energy-consuming apps and more load being applied compared to the prior cycle.

Now referring to FIG. 22, this chart 2200 continues with the example of FIG. 21 regarding more load being applied. As shown, at the beginning of partial charge, the line 2210 for actual discharge rate is lower than the baseline 2110 from FIG. 21 as expected, but then approaches and crosses the line 2110 unexpectedly beginning at point 2220 while the (higher) load remains the same. As such, this abnormality (higher voltage despite higher load) may be flagged consistent with present principles.

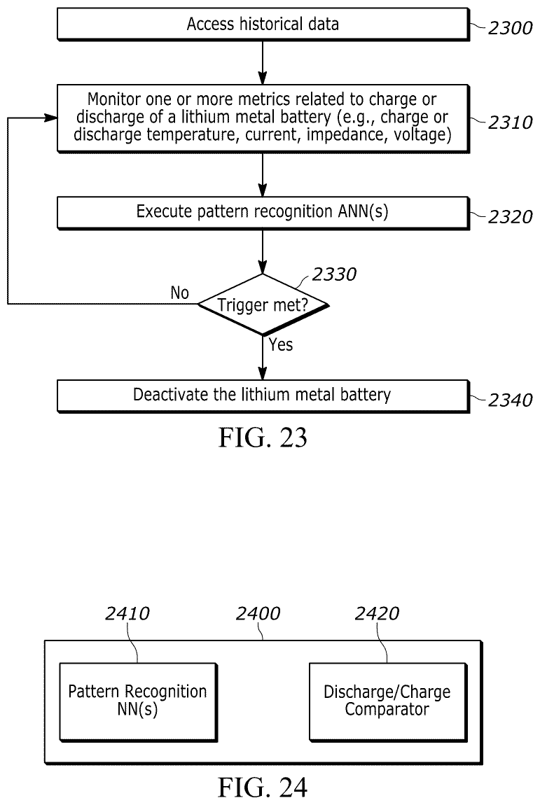

Continuing the detailed description in reference to FIG. 23, this figure shows example logic that may be executed by a processor system in a BMS, and/or by another processor system such as a CPU or DSP, consistent with present principles. Note that while the logic of FIG. 23 is shown in flow chart format, other suitable logic may also be used (e.g., state machine).

Beginning at block 2300, the system may access historical data regarding past full and partial charge and discharge cycles of a lithium metal battery consistent with present principles (e.g., to establish a baseline for a next expected charge or discharge as discussed above). Note here that the lithium metal battery might be a pre-lithiated lithium-silicon battery that has an anode that includes silicon, for example.

The logic may then proceed to block 2310 where the system may monitor one or more real-time metrics related to charge or discharge of the lithium metal battery over a number of charge and discharge cycles for the lithium metal battery. The system may do so to determine, based on the monitoring of the one or more metrics over the number of charge and discharge cycles for the lithium metal battery, that a trigger associated with excess lithium cumulation has been met. Artificial intelligence (AI)-based models may be used to do so, though rules-based algorithms may additionally or alternatively be used.

Thus, in one example at block 2320, the determination that the trigger has been met may be made by executing an artificial neural network (ANN) configured for pattern recognition. The ANN may include a convolutional neural network and/or feed-forward neural network trained for recognizing patterns in battery metrics to then generate an expected future charge or discharge voltage trend over time based on the current/real-time metrics fed into the model. In some examples, the model may also be configured to output an indication of whether an abnormality has been detected based on the real-time metrics and expected voltage trend, though this might also be determined external to the ANN but still by the processor system using the expected voltage trend output by the ANN itself.

Accordingly, in one example the system may provide the real-time metrics and past historical data as input to the ANN. The metrics may include real-time temperature, impedance, voltage, current, load, calendric and cyclic age, and/or other metrics. The ANN may then be executed by the system at block 2320 to generate an expected trend in light of the real-time metrics. Then at diamond 2330, the ANN may determine whether the aforementioned trigger has been met by analyzing the one or more real-time metrics from block 2310 (e.g., voltage) in comparison to the expected trend it generated based on the historical data for the one or more previous charge or discharge cycles, then providing an output indicating whether an abnormality has been detected and/or indicating that the trigger itself has been met based on the detected abnormality.

The ANN may thus provide the output indicating whether the trigger has been met to the operating environment executing external to the ANN according to one example. But regardless of whether the ANN or external operating environment determines that the trigger has been met, note that responsive to a negative determination at diamond 2330 (no trigger met), the logic may revert back to block 2310 and proceed again therefrom. However, responsive to determining that the trigger has in fact been met, the logic may instead proceed to block 2340.

At block 2340, responsive to determining that the trigger has been met, the system may deactivate the lithium metal battery. Deactivating the battery may include controlling circuitry internal or external to the battery to disconnect the battery from a device being powered by the battery. For example, the system may turn off a switch in the battery circuitry so that current can no longer flow external to the battery (e.g., to other components of a smartphone or laptop computer in which the battery is housed).

Additionally or alternatively, deactivating the battery may include fully discharging the battery, where a switch in the battery circuitry may be activated to provide a path to ground to accelerate discharge. In addition to or in lieu of the foregoing, a switch may be activated to provide current to a parasitic load within the battery itself or external to the battery to fully discharge the battery. In these contexts, full discharge for deactivating the battery is understood to be lower than a normal complete discharge allowed during regular battery operation which would still allow the battery to be charged again thereafter, since during full discharge for deactivation the battery is discharged near (or to) absolute zero to the point where the battery is spent and cannot be charged again.

Other techniques for battery deactivation may also be used, with it being understood that regardless of technique, battery deactivation may nonetheless include rendering the battery permanently inoperable in non-limiting examples such that it can no longer be charged or discharged, or otherwise rendering the battery permanently unable to provide current to the device in which it is disposed.

Referring back to the aforementioned metrics and providing certain examples consistent with present principles, note that the metrics may relate to temperature of the lithium metal battery during charge, temperature of the lithium metal battery during discharge, discharge current of the lithium metal battery, charge current of the lithium metal battery, voltage of the lithium metal battery during charge, voltage of the lithium metal battery during discharge, impedance of the lithium metal battery during charge, and/or impedance of the lithium metal battery during discharge. Other metrics might also be used where available (including real-time load on the battery), with it being further noted that impedance impacts current based on a given operating temperature according to the disclosure above.

Thus, in one particular example instance, the one or more metrics may relate to discharge current of the lithium metal battery under a first expected impedance (e.g., due to a given operating temperature), and/or charge current of the lithium metal battery under a second expected impedance (e.g., also due to a given operating temperature).

Also in one particular instance, the one or more metrics may relate to discharge current of the lithium metal battery while the lithium metal battery is within a first temperature range, and/or charge current of the lithium metal battery while the lithium metal battery is within a second temperature range. The first and second temperature ranges might be above or below an immediately previous temperature/range at which the battery was charged or discharged.

In terms of the trigger(s) themselves that are used by the system, one trigger might include deviation of the one or more metrics from an expected level for that metric for at least a threshold period of continuous time (e.g., through a fifty percent charge or discharge). This may be used as a trigger since the lack of return to expected “normal” at any point during the continuous period of time can indicate a runaway situation for which the battery should be deactivated.

Additionally or alternatively, the trigger may include a threshold number of times being reached, during a predefined time interval (e.g., one continuous, uninterrupted charge or discharge cycle whether partial or full), that the one or more real-time metrics deviate from respective expected levels and then return to respective expected levels. In some examples, the threshold number of times may be more than two times since one or two deviations with a subsequent return to normal might not indicate a runaway situation for which the battery should be deactivated since temporary fluctuations can be expected given the properties of the lithium metal battery. But three or more times could in fact indicate a runaway situation creating a safety hazard, which in turn may trigger battery deactivation.

Continuing the detailed description in reference to FIG. 24, this figure shows example AI model architecture that may be implemented consistent with present principles. Thus, an AI model 2600 may include pattern recognition neural networks (NNs) 2410 such as the aforementioned convolutional and/or feed-forward neural networks. The model 2400 may also include a discharge/charge trend comparator 2420. The comparator 2420 may be established by its own ANN or by an activation layer of the NNs 2410. In either case, the comparator 2420 may be configured to compare an expected trend (e.g., voltage trend) to an actual trend to determine whether a trigger has been met consistent with the disclosure above.

In terms of training, the model 2400 may be trained using one or more datasets of input battery metrics (e.g., voltage, temperature, impedance, current, load, calendric and cyclic age, etc.) and corresponding ground truth trends expected from the relevant input metrics. To this end, supervised learning may be used, with it being further understood that self-learning, reinforcement learning, and other machine learning techniques may also be used.

During deployment, the model 2400 may receive historical trend data as well as real-time battery metrics as input. The inputs may then be processed to, using pattern recognition, generate an expected voltage trend for the battery according to the current real-time metrics. The model 2400 may then continue to monitor the battery metrics as charge or discharge continues to subsequently determine whether one of the aforementioned triggers has been met, analyzing follow-on real-time metrics in comparison to the expected trend it generated to then provide an output indicating whether an abnormality has been detected and/or indicating that the relevant trigger has been met based on a detected abnormality.

Components included in one embodiment can be used in other embodiments in any appropriate combination. For example, any of the various components described herein and/or depicted in the Figures may be combined, interchanged or excluded from other embodiments.

It is to be understood that whilst present principles have been described with reference to some example embodiments, these are not intended to be limiting, and that various alternative arrangements may be used to implement the subject matter claimed herein. Accordingly, while particular techniques and devices are herein shown and described in detail, it is to be understood that the subject matter which is encompassed by the present application is limited only by the claims.

What is claimed is:

1. A device, comprising:
a processor system; and
storage accessible to the processor system and comprising instructions executable by the processor system to:
monitor one or more metrics related to charge or discharge of a lithium metal battery over a number of charge and discharge cycles for the lithium metal battery;
based on the monitoring of the one or more metrics over the number of charge and discharge cycles for the lithium metal battery, determine that a trigger associated with excess lithium cumulation on an anode of the battery has been met; and
responsive to determining that the trigger has been met, deactivate the lithium metal battery.

2. The device of claim 1, wherein the one or more metrics relate to one or more of: temperature of the lithium metal battery during charge, temperature of the lithium metal battery during discharge.

3. The device of claim 1, wherein the one or more metrics relate to one or more of: discharge current of the lithium metal battery, charge current of the lithium metal battery.

4. The device of claim 1, wherein the one or more metrics relate to one or more of: discharge current of the lithium metal battery under a first expected impedance, charge current of the lithium metal battery under a second expected impedance.

5. The device of claim 1, wherein the one or more metrics relate to one or more of: discharge current of the lithium metal battery while the lithium metal battery is within a first temperature range, charge current of the lithium metal battery while the lithium metal battery is within a second temperature range.

6. The device of claim 1, wherein the one or more metrics relate to one or more of: voltage of the lithium metal battery during charge, voltage of the lithium metal battery during discharge.

7. The device of claim 1, wherein the trigger comprises detection that the one or more metrics have deviated from respective expected levels for at least a threshold period of continuous time.

8. The device of claim 1, wherein the trigger comprises detection that a threshold number of times have been reached, during a predefined time interval, where the one or more metrics deviated from respective expected levels and then returned to respective expected levels.

9. The device of claim 8, wherein the threshold number of times is more than two times.

10. The device of claim 1, wherein the determination that the trigger has been met is made using an output from one or more trained artificial neural networks (ANNs) configured for pattern recognition.

11. The device of claim 10, wherein the one or more trained ANNs are executed to determine that the trigger has been met by analyzing the one or more metrics in relation to an expected trend determined from historical data for one or more previous charge or discharge cycles of the lithium metal battery.

12. The device of claim 1, wherein the lithium metal battery is a lithium-silicon battery.

13. The device of claim 12, wherein an anode of the lithium metal battery comprises silicon.

14. The device of claim 1, comprising the lithium metal battery.

15. A method, comprising:
analyzing one or more metrics related to charge or discharge of a lithium metal battery over a number of charge and discharge cycles for the lithium metal battery;
based on the analyzing of the one or more metrics over the number of charge and discharge cycles for the lithium metal battery, determining that a trigger associated with excess lithium cumulation has been met; and
responsive to determining that the trigger has been met, deactivating the lithium metal battery.

16. The method of claim 15, wherein deactivating the lithium metal battery comprises controlling circuitry to disconnect the battery from a device being powered by the battery.

17. The method of claim 15, wherein the one or more metrics relate to one or more of: temperature, current, impedance, voltage.

18. The method of claim 15, wherein the trigger comprises one or more of:
detection that the one or more metrics have deviated from an expected level for at least a threshold period of continuous time; and/or detection that a threshold number of times have been reached, during a predefined time interval, where the one or more metrics deviated from respective expected levels and then returned to respective expected levels.

19. A battery management system (BMS) comprising a processor system configured to:
analyze one or more metrics related to charge or discharge of a battery over a number of charge and discharge cycles for the battery;
based on the analysis of the one or more metrics over the number of charge and discharge cycles for the battery, determine that a trigger associated with excess battery material cumulation has been met; and
responsive to determining that the trigger has been met, deactivate the battery.

20. The BMS of claim 18, wherein:
the battery is a lithium-metal battery;
the one or more metrics relate to one or more of: temperature, current, impedance, voltage; and
the trigger comprises one or more of:
detection that the one or more metrics have deviated from an expected level for at least a threshold period of continuous time; and/or
detection that a threshold number of times have been reached, during a predefined time interval, where the one or more metrics deviated from respective expected levels and then returned to respective expected levels.
